(19) United States
(12) Patent Application Publication
(10) Pub. No.: US 2025/0374719 A1
(43) Pub. Date: Dec. 4, 2025

(54) PACKAGE AND OPTOELECTRONIC DEVICE INCLUDING THEREOF

(71) Applicant: LITE-ON TECHNOLOGY CORPORATION, TAIPEI CITY (TW)

(72) Inventors: CHEN-HSIU LIN, NEW TAIPEI CITY (TW); HSUN-YU LI, Taoyuan City (TW)

(21) Appl. No.: 19/220,114

(22) Filed: May 28, 2025

Related U.S. Application Data
(60) Provisional application No. 63/653,263, filed on May 30, 2024.

(30) Foreign Application Priority Data
Apr. 30, 2025 (CN) 202520854841.2

(51) Int. Cl. H10H 20/85; H10H 20/852; H10H 20/856

(52) U.S. Cl. CPC H10H 20/8508; H10H 20/852; H10H 20/856

(57) ABSTRACT

A package includes a first frame, a second frame and a package body. The first frame includes a first body and at least one first protrusion. The at least one first protrusion is disposed on the first body. The second frame is arranged opposite to the first frame, and includes a second body and at least one second protrusion. The at least one second protrusion is disposed on the second body. The package body encapsulates the first frame and the second frame, and the first protrusion and the second protrusion are exposed on a top surface of the package body. In a horizontal direction, a distance between the first protrusion and the second protrusion is smaller than a distance between the first body and the second body.

### CROSS-REFERENCE TO RELATED PATENT APPLICATION

This application claims the benefit of priorities to the U.S. Provisional Patent Application Ser. No. 63/653,263, filed on May 30, 2024, and to the patent of People's Republic of China, No. 202520854841.2, filed on Apr. 30, 2025, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a package, and more particularly to a package capable of increasing an area of an optoelectronic chip.

### BACKGROUND OF THE DISCLOSURE

Existing optoelectronic devices provide a package featuring a light-emitting groove that utilizes the principle of light reflection. While this structure offers optional reflective effects, it suffers from limitations such as the dimensions of the light-emitting groove constraining the size of the optoelectronic chip.

Another approach involves a flat-type ceramic package, which allows the chip size to be maximized. However, the high cost of ceramic materials poses challenges for manufacturing processes thereof. In addition, the total height of such a package is also limited.

Therefore, how to design a package that streamlines the size of the optoelectronic device, enhances light-emitting efficiency, and reduces manufacturing costs has become an important issue to be addressed in the relevant art.

### SUMMARY OF THE DISCLOSURE

The purpose of the present disclosure is to provide a package and an optoelectronic device including thereof, so as to address at least one of the problems mentioned above.

The package includes: a first frame, a second frame, and a package body. The first frame includes at least one first body and at least one first protrusion disposed on the first body. The second frame is disposed opposite to the first frame and includes at least one second body and at least one second protrusion disposed on the second body. The package body encapsulates the first frame and the second frame, and the first and second protrusions protrude from a top surface of the package body. In a horizontal direction, the distance between the first protrusion and the second protrusion is less than the distance between the first body and the second body.

The present disclosure further provides an optoelectronic device, including a package and at least one optoelectronic chip. The optoelectronic chip is disposed on the top surface of the package body and is electrically connected to the first and second protrusions.

Therefore, in the package provided by the present disclosure, the first frame, the second frame, and the package body having excellent bonding effect, and a packaging process without setting up a lead frame can be realized, the installation of the optoelectronic chip can increase the area of the optoelectronic chip, and the process can be simplified to improve the yield.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic cross-sectional view of a package according to the present disclosure;

FIG. 2 is a bottom view of the embodiment shown in FIG. 1;

FIG. 3 is a schematic view of a lead frame array as shown in FIG. 1;

FIGS. 4 to 7 are schematic views of an optoelectronic device according to the present disclosure, respectively;

FIG. 8 is a schematic cross-sectional view of a package according to another embodiment of the present disclosure;

FIG. 9 is a bottom view of the embodiment shown in FIG. 8;

FIG. 10 is a schematic view of a lead frame array in the embodiment shown in FIG. 8;

FIG. 11 is a schematic perspective view of the optoelectronic device according to one embodiment of the present disclosure;

FIG. 12 is a schematic cross-sectional view of the package according to one embodiment of the present disclosure;

FIG. 13 is a bottom view of the embodiment shown in FIG. 12;

FIG. 14 is a schematic view of the lead frame array composed of the first frame and the second frame in the embodiment shown in FIG. 12;

FIG. 15 to FIG. 20 are respectively schematic views of an optoelectronic device according to one embodiment of the present disclosure;

FIG. 21 is a schematic view of an optoelectronic device according to one embodiment of the present disclosure; and

FIGS. 22 and 23 are respectively a bottom view and a top view of the package in the embodiment shown in FIG. 21.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

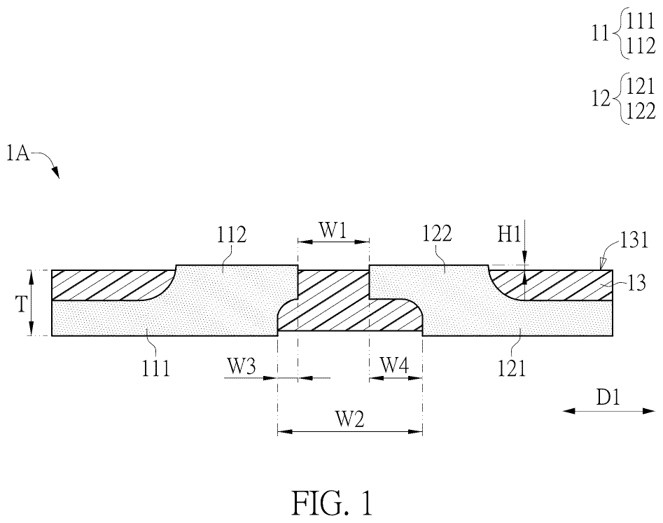

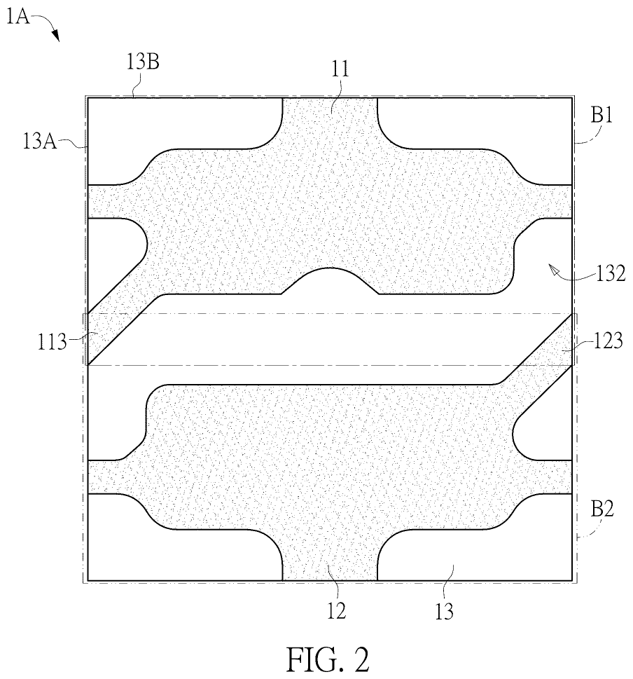

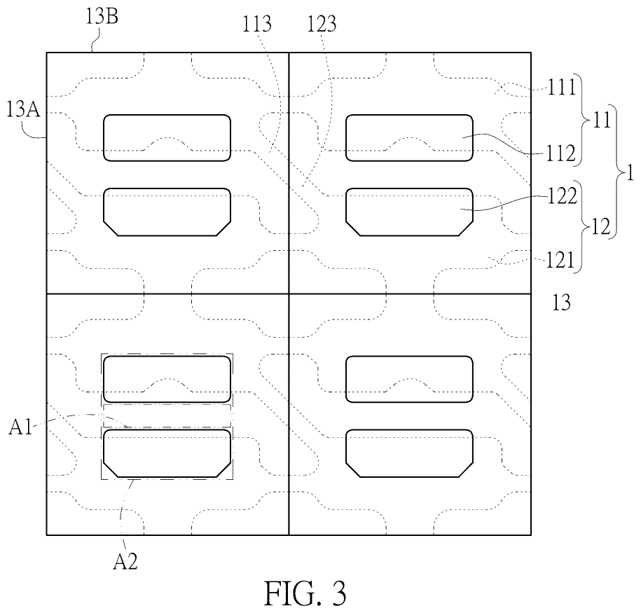

Referring to FIG. 1 to FIG. 3, FIG. 1 is a schematic cross-sectional view of a package 1A according to the present disclosure, FIG. 2 is a bottom view of the embodiment shown in FIG. 1, and FIG. 3 is a schematic view of a lead frame array composed of the first frame and the second frame as shown in FIG. 1.

The package 1A includes: a first frame 11, a second frame 12, and a package body 13. The first frame 11 includes a first body 111 and a first protrusion 112, which is located on the first body 111. The second frame 12 is disposed opposite to the first frame 11 and includes a second body 121 and a second protrusion 122, which is located on the second body 121. The package body 13 encapsulates both the first frame 11 and the second frame 12, and the first protrusion 112 and the second protrusion 122 protrude from the top surface 131 of the package body 13.

According to some embodiments, the package body 13 is made of an opaque material, in particular, epoxy resin filled with titanium dioxide (TiO₂). In a horizontal direction D1, a distance W1 between the first protrusion 112 and the second protrusion 122 is smaller than a distance W2 between the first body 111 and the second body 121, as shown in FIG. 1. Moreover, the spacing between the first protrusion 112 and the second protrusion 122 may be suitably adjusted according to the pitch of the PN bonding pads of the chip. As shown in FIG. 1, the cross-sectional profile of the first frame 11 is substantially Z-shaped, and the second frame 12 also has a mirrored Z-shaped cross-section.

In other words, the first frame 11 and the second frame 12 generally have a mirror-symmetrical stepped structure (including the first protrusion 112 and the second protrusion 122). In a vertical direction, the first protrusion 112 and the second protrusion 122 extend outward toward the opposite frame, with a protrusion distance of 0-100 μm.

Specifically, on a same side, a distance W3 between a first side end surface of the first protrusion 112 (facing the second protrusion 122) and a first side-portion end surface of the first body 111 is 0-100 μm. Likewise, on a same side, a distance W4 between a second side end surface of the second protrusion 122 (facing the first protrusion 112) and a second side-portion end surface of the second body 121 is 0-100 μm. Furthermore, when the exposed shapes and sizes of the bottom surfaces of the first body 111 and the second body 121 are similar, an identification structure (e.g., a groove) is further provided on the second body 121 for electrical recognition purposes. Therefore, W4 is preferably greater than W3, or vice versa.

Referring again to FIG. 1 and FIG. 3, the first frame 11 and the second frame 12 respectively have mirror-symmetrical Z-shaped cross-sections formed by upper and lower etching, and the first protrusion 112 and the second protrusion 122 are also mirror-symmetrical. The height difference H1 between the first protrusion 112 and the second protrusion 122 protruding from the top surface of the package body 13 is greater than 0 μm and less than 15 μm. This configuration helps prevent an encapsulant overflow onto a metal surface, which could lead to poor solder wetting on the electrical ends at the bottom of the chip (height difference of approximately 3 μm), and reduces the risk of short circuits. In some embodiments, exposed surface areas of the first protrusion 112 and the second protrusion 122 are approximately ¼ to ½ of the top surface area of the package body 13. Compared to a wire-bonding frame design, this structure allows for a greater variety of optoelectronic chip sizes. In some embodiments, an area corresponding to the first protrusions 112 and the second protrusions 122 defines a die-bonding area A2, where an optoelectronic chip 15 is mounted. The surface area of the optoelectronic chip 15 is approximately 1-1.5 times the size of die-bonding area A2. This structural design increases the usable chip area within the package. In the embodiment shown in FIG. 1, a wire-bond-free flip-chip process is implemented, allowing for up to a 55% increase in chip area, while simplifying the process and improving yield.

In some embodiments, the first frame 11 and the second frame 12 undergo upper and lower etching to form Z-shaped mirror-symmetric structures and are roughened by sandblasting. As shown in FIG. 1, the first frame 11 and the second frame 12 are further joined with the package body 13 in a Z-axis (thickness) direction to improve moisture resistance and reinforce structural adhesion, particularly when the thickness T of the package 1A is 0.1 to 0.25 mm (i.e., the frames have a thickness of 0.1 to 0.25 mm joined with the package body 13). According to some embodiments, a bottom surface of the first body 111 and a bottom surface of the second body 121 are exposed from the bottom surface 132 of the package body 13, with a protrusion height of greater than 0 μm and less than 15 μm, preferably 6 to 12 μm. As shown in FIG. 2, the package 1A has two opposing side edges 13A, each provided with three electrical ends from a lead frame 1. On the other two opposite side edges 13B, centered supporting ends are respectively disposed. The three electrical ends on each 13A side edge include two types of electrical properties. More specifically, on the two opposing side edges 13A, the two center ends have different electrical properties. Likewise, the centered supporting ends on the two opposite side edges 13B also have different electrical properties.

As shown in FIG. 3, the frame array includes a zigzag-shaped bridge configuration. One frame array is composed of the first frame 11 and the second frame 12. In the horizontal direction, adjacent frame arrays are connected by diagonal extension connection portions, which include a first connection portion 113 and a second connection portion 123. This design resolves the problem of isolated islands in a frame array. Moreover, to enhance the structural stability of the lead frame and its bonding with the package body 13, the connection portions 113 and 123 extend across half of the package body 13. In other words, the ends of the connection portions 113 and 123 preferably extend beyond the midpoint or more of the two opposing side edges 13A. Furthermore, as shown in FIG. 2, an area containing the first frame is defined as a first area B1, and an area containing the second frame 12 is defined as a second area B2. The first connection portion 113 extends outward into the overlapping area between the first area B1 and the second area B2. Similarly, the second connection portion 123 extends into this overlapping area. This also enhances the stability of the lead frame and its adhesion to the package body 13. The first protrusion 112 and the second protrusion 122 together define a die-bonding area A2 (which includes the area A1 between the protrusions), providing a planar (or slightly elevated) surface that facilitates the soldering process between the anode and cathode of a large-sized optoelectronic chip 15 and the corresponding two protrusions (first protrusion 112 and second protrusion 122).

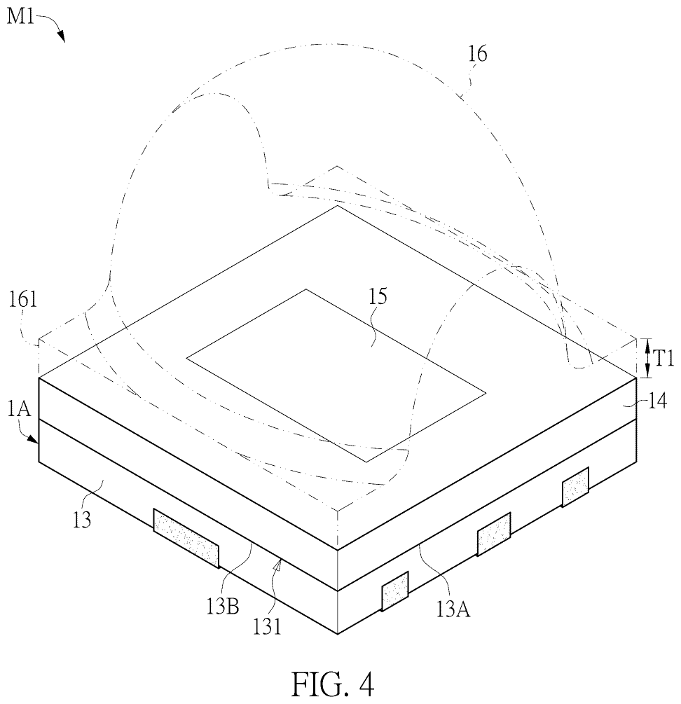

Please refer to FIGS. 4 to 7, which respectively show perspective views of optoelectronic devices M1, M2, M3, and M4, according to the package shown in FIG. 1 of the present disclosure. In these embodiments, each of the optoelectronic devices M1, M2, M3, and M4 further includes an optoelectronic chip 15 and a covering layer 16. The optoelectronic chip 15 is disposed on the top surface 131 of the package body 13 and is electrically connected to the first protrusion 112 and the second protrusion 122. The covering layer 16 encapsulates the optoelectronic chip 15 and the exposed top surface 131 of the package body 13, serving to protect the optoelectronic chip 15 and prevent moisture ingress. Additionally, the covering layer 16 may be formed as a lens with curvature or planar surface. In the embodiments shown in FIG. 4 to FIG. 7, the covering layer 16 is an external lens with curvature. Each of the optoelectronic devices M1 and M3 further includes a reflective layer 14 disposed on the top surface 131 of the package body 13 and surrounding the optoelectronic chip 15. Furthermore, a top surface of the reflective layer 14 is flush with a top surface of the optoelectronic chip 15. The covering layer 16 encapsulates the aforementioned flush top surfaces of the optoelectronic chip 15 and the reflective layer 14, especially on the top surface of the optoelectronic chip 15 exposed from the reflective layer 14. According to some embodiments, the reflective layer 14 is composed of resin and diffuser particles, such as silicone and titanium dioxide (TiO₂).

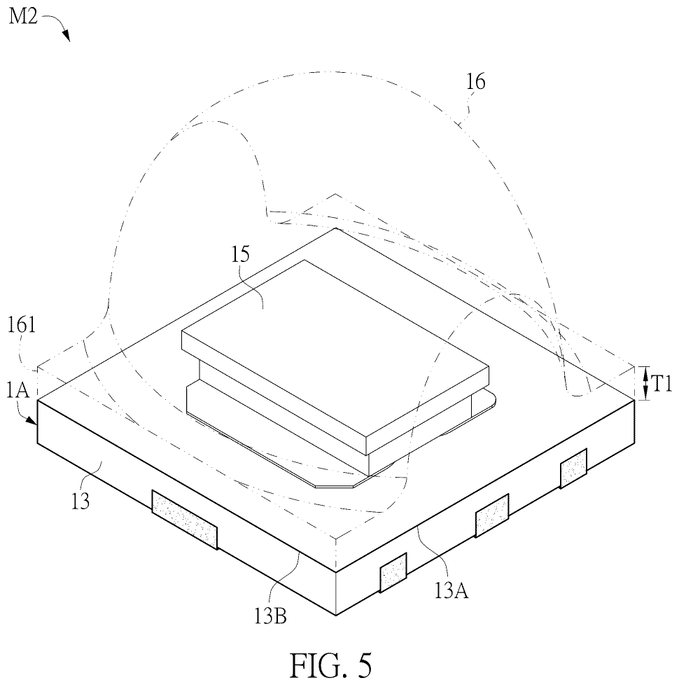

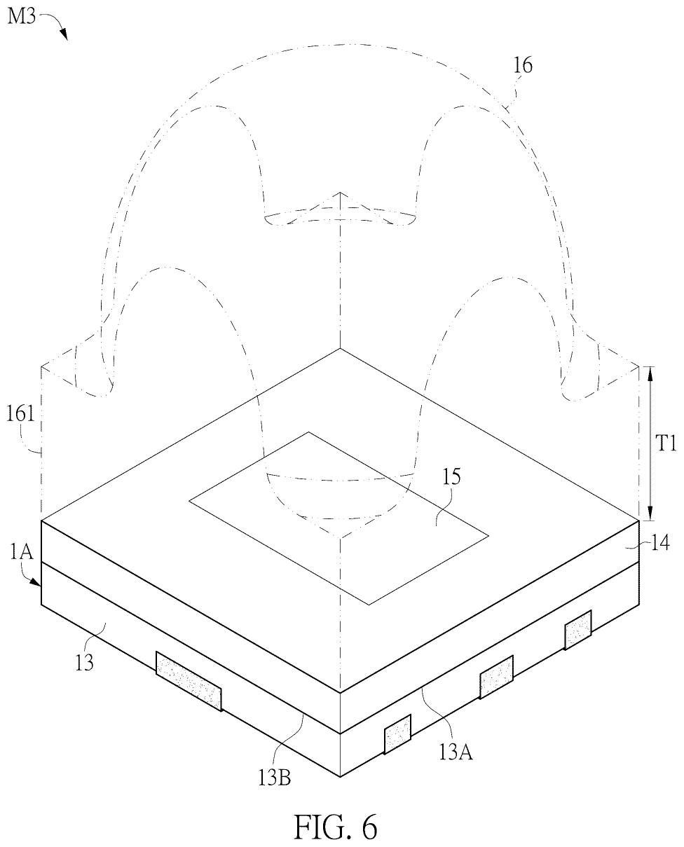

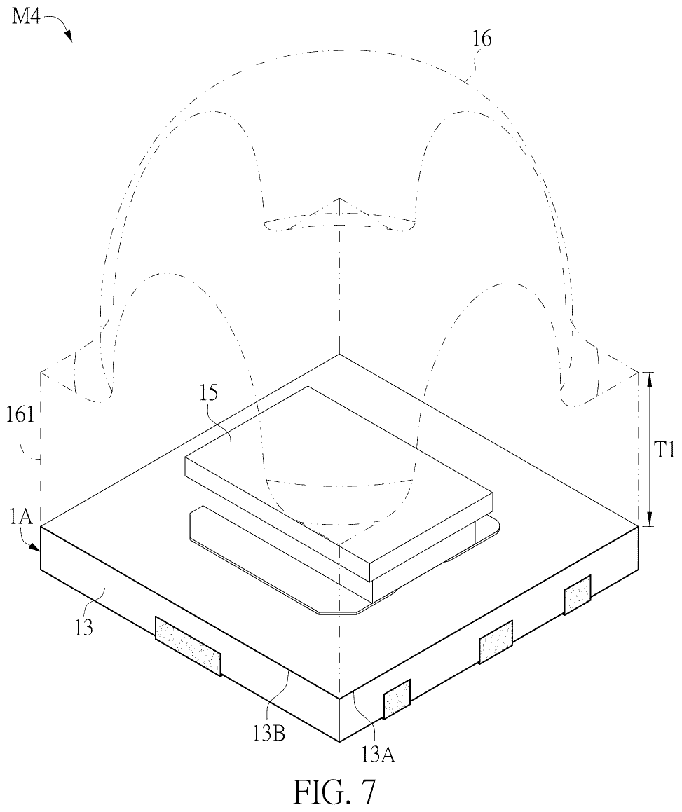

The following describes the viewing angles of the respective optoelectronic devices. In some embodiments, the covering layer 16 includes a base 161 and a convex lens formed on the base 161. According to some embodiments, a thickness T1 of the base 161 ranges from 0.05 to 0.50 mm (see FIG. 4 to FIG. 7). When the convex lens is an asymmetrical lens with chamfered edges on two sides, the viewing angles of the optoelectronic devices differ in two emission directions. For example, in the embodiments shown in FIG. 4 and FIG. 5, in the direction corresponding to side edge 13A of the package body 13, the viewing angle of the optoelectronic devices M1 and M2 is 105 degrees, while in the direction corresponding to side edge 13B, the viewing angle is 70 degrees. When the convex lens is a symmetrical lens with chamfered edges on all four sides, the viewing angles of the optoelectronic chip 15 in both emission directions range from 90 to 125 degrees. For example, in the embodiments shown in FIG. 6 and FIG. 7, in the direction corresponding to side edge 13A of the package body 13, the viewing angle of the optoelectronic devices M3 and M4 is 125 degrees, while in the direction corresponding to side edge 13B, the viewing angle is 90 degrees. In addition, according to the embodiments shown in FIG. 4 and FIG. 6, optoelectronic devices M1 and M3 include the reflective layer 14. Compared to optoelectronic devices M2 and M4 that do not include a reflective layer 14, the brightness of the optoelectronic devices with the reflective layer 14 is improved by approximately 10-15%.

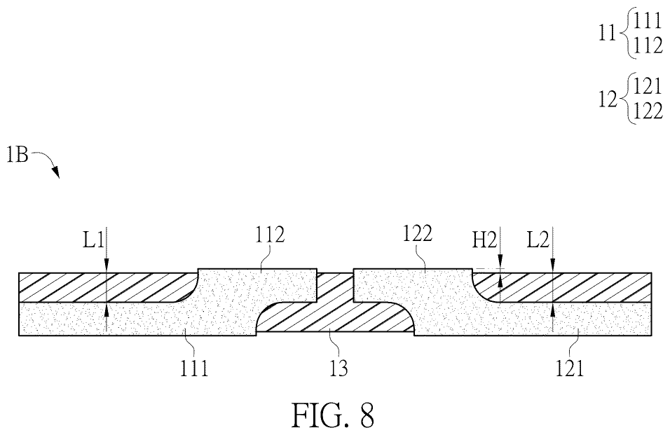

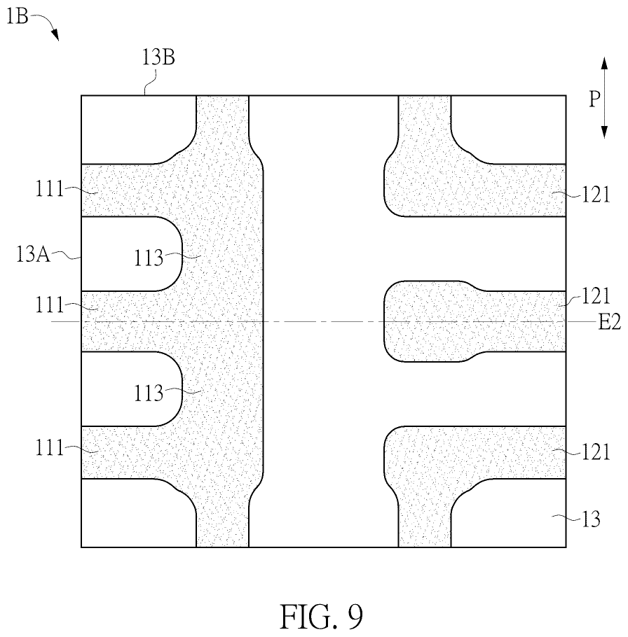

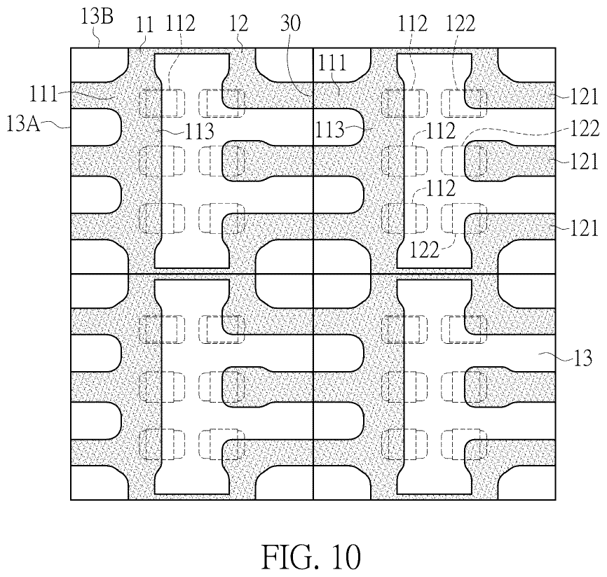

FIG. 8 is a cross-sectional schematic view of a package 1B according to one embodiment of the present disclosure, FIG. 9 is a bottom view of the embodiment shown in FIG. 8, and FIG. 10 is a schematic view of the lead frame array including the first frame and second frame in the embodiment shown in FIG. 8.

The package 1B includes a first frame, a second frame, and a package body 13. The first frame includes a first frame 11, which has a plurality of first bodies 111, a plurality of connection portions 113, and a plurality of first protrusions 112. The second frame 12 includes a plurality of second bodies 121 and a plurality of second protrusions 122, wherein each second protrusion 122 is disposed on a corresponding second body 121. Taking FIGS. 9 and 10 as examples, the first frame 11 includes three first bodies 111, two connection portions 113, and three first protrusions 112. The three first bodies 111 are arranged in a direction P, with adjacent first bodies 111 connected via the connection portions 113. The plurality of connection portions 113 extend across one half of the package body 13. The three first protrusions 112 are respectively disposed on the three first bodies 111. In a cross-sectional view along the central vertical plane E2, the first frame 11 is Z-shaped. The second frame 12 includes three second bodies 121 and three second protrusions 122. The three second bodies 121 are arranged along the direction P and are independent and unconnected. The three second protrusions 122 are also arranged along the direction P. In a cross-sectional view along the central vertical plane E2, the second frame 12 is Z-shaped. The second frame 12 is disposed opposite to the first frame 11, with the three second protrusions 122 respectively facing and corresponding to the three first protrusions 112 in mirror symmetry. As shown in FIG. 8, in a vertical direction, the plurality of first protrusions 112 and second protrusions 122 respectively protrude from the first frame 11 and the second frame 12 toward opposite sides. In other words, in the horizontal direction, a distance between each corresponding pair of first protrusion and second protrusion is less than a distance between the corresponding first body 111 and second body 121. In other words, the package body 13 encapsulates the first frame 11 and the second frame 12, with the first protrusions 112 and the second protrusions 122 exposed from the top surface 131 of the package body 13. Each of the first frame 11 and the second frame 12 has upper and lower etched structures, forming a cross-section that is mirror-symmetric in a Z-shape.

According to the embodiment shown in FIG. 8, a thickness T of the package 1B ranges from 0.1 to 0.25 mm. The height difference H2 between the three first protrusions 112 and the three second protrusions 122 exposed on the top surface of the package body 13 is greater than 0 and less than 15 μm, and preferably ranges from 6 to 12 μm. This configuration prevents overflow of the encapsulant onto the metal surface, which could lead to poor solderability on the chip's bottom-side electrical ends (with a typical height difference of about 3 μm), and reduces the risk of short-circuiting. The plurality of first bodies 111 and second bodies 121 are also exposed from the bottom surface of the package body 13, preferably to a height less than 15 μm. Adjacent first bodies 111 are connected, while the three second bodies 121 of the second frame 12 are independent and unconnected. This structure enables multi-die flip-chip processes, simplifies manufacturing steps, improves yield, and supports miniaturized product design.

According to the embodiment shown in FIG. 9, the total exposed area of the first protrusions 112 and second protrusions 122 is approximately ¼ to ½ of the top surface area of the package body 13.

The first frame 11 and second frame 12 undergo upper and lower etching processes to form a Z-shaped mirror-symmetrical cross-section and are roughened by sandblasting. The frame assembly is combined with the package body 13 at a thickness of 0.1 to 0.25 mm. Under encapsulation by the package body 13, the structure helps slow moisture ingress and reinforces the mechanical integrity of the frame assembly. The package 1B has two opposite side edges 13A, each of which includes three electrical ends of the lead frame 1. The other two opposite side edges 13B each include two supporting ends (as can be referred to in FIG. 9).

As shown in FIG. 10, the frame array presents an “H”-shaped bridge connection. The first frame 11 and second frame 12 define a frame assembly. In a horizontal direction, between adjacent units of the frame array, the second frame 12 is connected to the first frame 11 via a plurality of extending connection portions 30. This structure addresses the issue of isolated islands in the frame array. According to the design of the first frame 11 and the second frame 12, the circuits are configured on the same polarity (common cathode or common anode). The optoelectronic chip 15 is mounted co-planarly on the first protrusions 112 and second protrusions 122. When the frame array is molded with the package body 13, it maintains structural stability.

In some embodiments, the distances L1 and L2 between the first bodies 111, the second bodies 121, and the top surface of the package body 13 are preferably ¼ to ½ of the total thickness of the frame assembly.

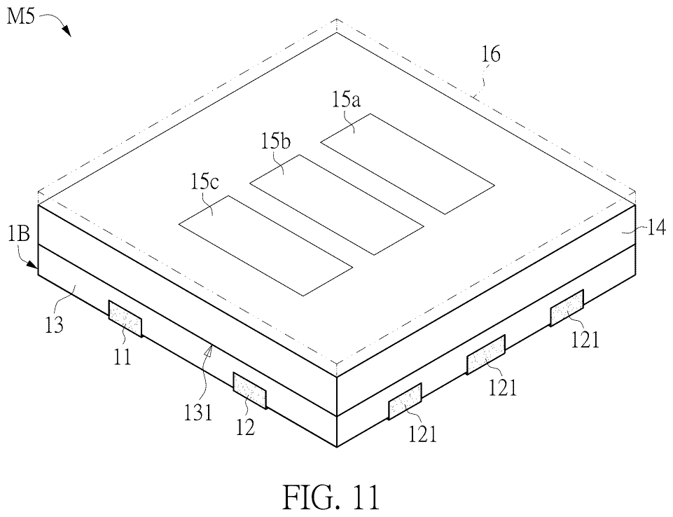

Reference is made to FIG. 11, which is a three-dimensional schematic view of the optoelectronic device M5 according to one embodiment of the present disclosure. In this embodiment, the employed package 1B corresponds to the embodiment shown in FIG. 8. The optoelectronic device M5 includes a first optoelectronic chip 15a, a second optoelectronic chip 15b, a third optoelectronic chip 15c, a reflective layer 14, and a covering layer 16. The first optoelectronic chip 15a is disposed on the top surface of the package body 13 and is electrically connected to the second protrusion 122 and the first protrusion 112 opposite to the second protrusion 122. The second optoelectronic chip 15b is also disposed on the top surface 131 of the package body 13 and electrically connected to the second protrusion 182 and the first protrusion 112 that is opposite to the second protrusion 182. The third optoelectronic chip 15c is similarly disposed on the top surface 131 of the package body 13 and electrically connected to the second protrusion 192 and the first protrusion 112 that is opposite to the second protrusion 192. The covering layer 16 is disposed over the first, second, and third optoelectronic chips. In this embodiment, the covering layer 16 is an external flat lens. The reflective layer 14 is disposed on the top surface 131 of the package body 13 and laterally surrounds the first, second, and third optoelectronic chips. According to some embodiments, the reflective layer 14 is composed of resin and diffuser such as silicone and titanium dioxide (TiO₂).

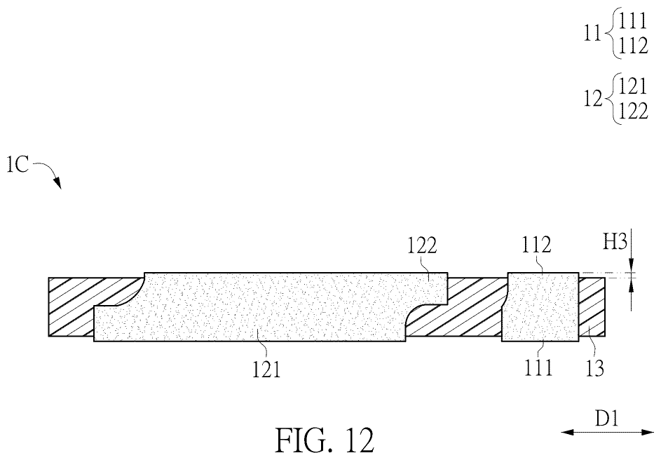

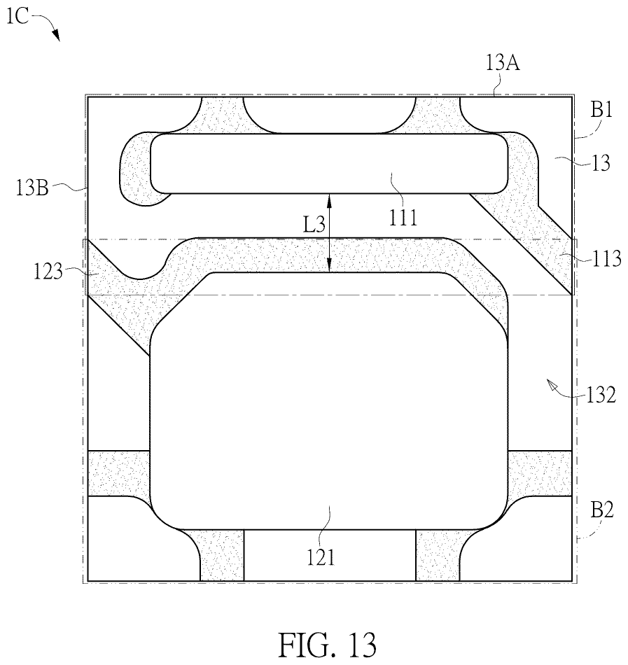

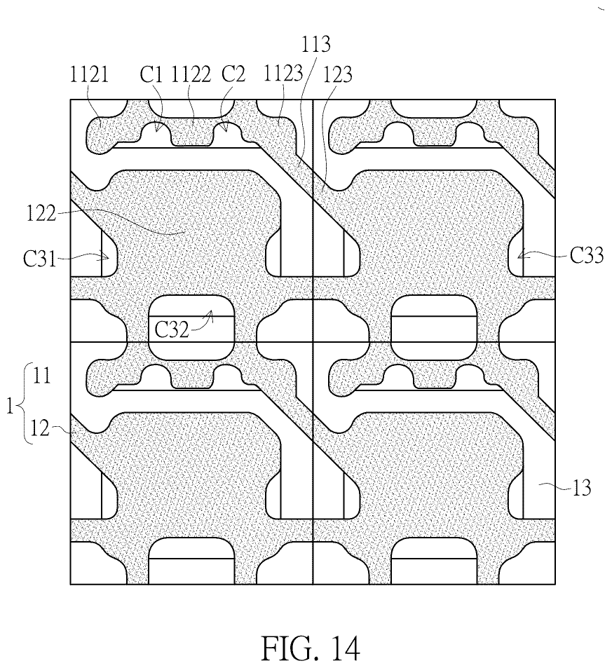

Referring to FIG. 12 to FIG. 14, FIG. 12 is a cross-sectional schematic view of the package 1C according to one embodiment of the present disclosure. FIG. 13 is a bottom view of the embodiment shown in FIG. 12. FIG. 14 is a schematic view of the frame array composed of the first frame 11 and the second frame 12 in the embodiment shown in FIG. 12. The package 1C includes a first frame 11, a second frame 12, and a package body 13. The first frame 11 includes a first body 111 and the first protrusions 112. In this embodiment, the first protrusions 112 include a first lateral protrusion 1121, a first central protrusion 1122, and a first connecting protrusion 1123. These protrusions are spaced apart on the first body 111, forming a first groove C1 between the first lateral protrusion 1121 and the first central protrusion 1122, and a second groove C2 between the first central protrusion 1122 and the first connecting protrusion 1123. The second frame 12 is disposed opposite to the first frame 11. The second frame 12 includes a second body 121 and second protrusions 122. The second protrusions 122 are disposed on the second body 121, surrounding the periphery of the second body 121 and forming a plurality of grooves C3. The second protrusions 122 protrude in the horizontal direction D1 toward the first central protrusion 1122 and extend beyond one side surface of the second body 121. The package body 13 encapsulates both the first and second frames 11 and 12. The first groove C1, second groove C2, and a plurality of grooves C3 on the frame enhance the bonding strength between the frame and the package body 13. Additionally, by having the package body 13 laterally cover the lead frame 1, the sidewalls of the package 1C exhibit uniform thickness. The first lateral protrusion 1121, the first central protrusion 1122, first connecting protrusion 1123, and the second protrusions 122 are exposed on the top surface 131 of the package body 13. In this embodiment, the bottoms of the second body 121 and the first body 111 are exposed on the bottom surface 132 of the package body 13. As shown in FIGS. 13-14, the two electrical ends of the lead frame 1 are respectively disposed on the two opposite side edges 13A of the package body 13. On one side edge 13A, the two electrical ends extend from the second protrusions 122 of the second frame 12. On the other side edge 13A, the two electrical ends extend from the first lateral protrusion 1121 and the first connecting protrusion 1123 of the first frame 11. The two supporting ends of the lead frame 1 are respectively disposed on the two opposite side edges 13B of the package body 13. On one side edge 13B, the two supporting ends differ electrically, while on the other side 13B, the two supporting ends are electrically identical.

As also shown in FIG. 13 and FIG. 14, the first frame 11 and the second frame 12 jointly define a lead frame 1. The first frame 11 includes a first cantilevered connection portion 113, and the second frame 12 includes a second cantilevered connection portion 123. In the horizontal direction, adjacent lead frames 1 are connected by obliquely extending the two adjacent first cantilevered connection portion and the second cantilevered connection portion. This arrangement addresses the issue of “island” isolation (as can be referred to in FIG. 14). As shown in FIG. 13, the region where the first frame 11 is located is defined as the first region B1, and the region of the second frame 12 is defined as the second region B2. The cantilevered connection portion 113 extends into region B2 from the exposed end of side 13B. The cantilevered connection portion 113 can also extend outward into the overlapping area between regions B1 and B2, thereby enhancing the mechanical strength of the package 1C.

According to some embodiments, the plurality of grooves C3 on the second frame 12 can be roughened via sandblasting, further enhancing the bonding between the lead frame (11 and 12) and the package body 13, particularly when the package 1C has a thickness less than 0.25 mm. The structure of the first protrusions 111 and second protrusions 121 maximizes the usable area for the optoelectronic chips. Thereby improving viewing efficiency. In some embodiments, the chip area increases by 34%, and luminous efficiency improves by 30%.

As shown in FIG. 13, the bottom of the second body 121 has a trapezoidal shape. This large trapezoidal area provides excellent heat dissipation while maintaining a robust and seamless soldering interface, thereby avoiding burr issues at the soldering joints during dicing.

In this embodiment, the plurality of grooves C3 include a first lateral groove C31, a central groove C32, and a second lateral groove C33. The first and second lateral grooves C31 and C33 are symmetrically arranged with respect to the central axis CL of the central groove C32.

According to some embodiments, a distance L3 between the first body 111 and the second body 121 ranges from 0.12 mm to 0.5 mm. In the horizontal direction D1, a distance between the first central protrusion 1122 of the first protrusions 112 and the second protrusions 122 is smaller than a distance L3 between the first body 111 and the second body 121, as shown in FIG. 13.

According to the embodiment shown in FIG. 12, a thickness T of the package 1C is between 0.1 mm and 0.25 mm. A height difference H3 between the first protrusions 112 and the second protrusions exposed on the top surface of the package body 13 is less than 15 μm and greater than 0, preferably between 6 μm and 12 μm. This helps prevent the encapsulant from overflowing onto the metal surface, which could lead to poor solderability at the chip's bottom electrical end (with a height difference of about 3 μm), and reduces the risk of short-circuiting. The first body 111 and the second body are also exposed on the bottom surface of the package body 13 by less than 15 μm and more than 0 μm, preferably 6-12 μm.

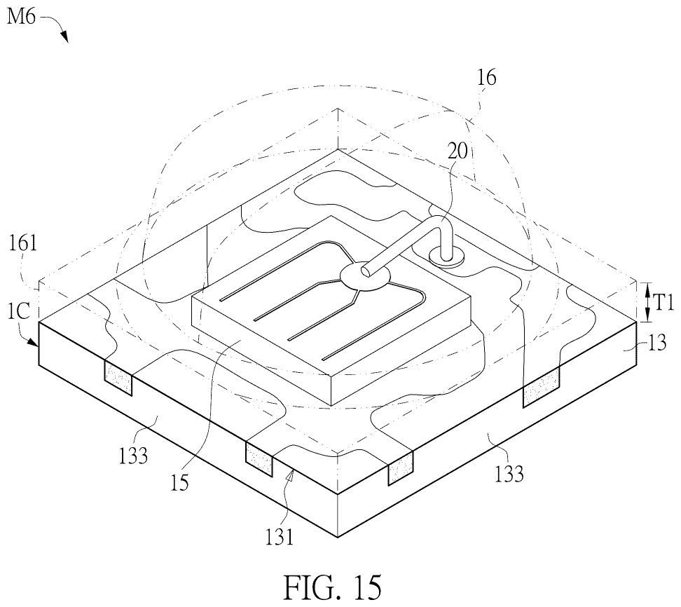

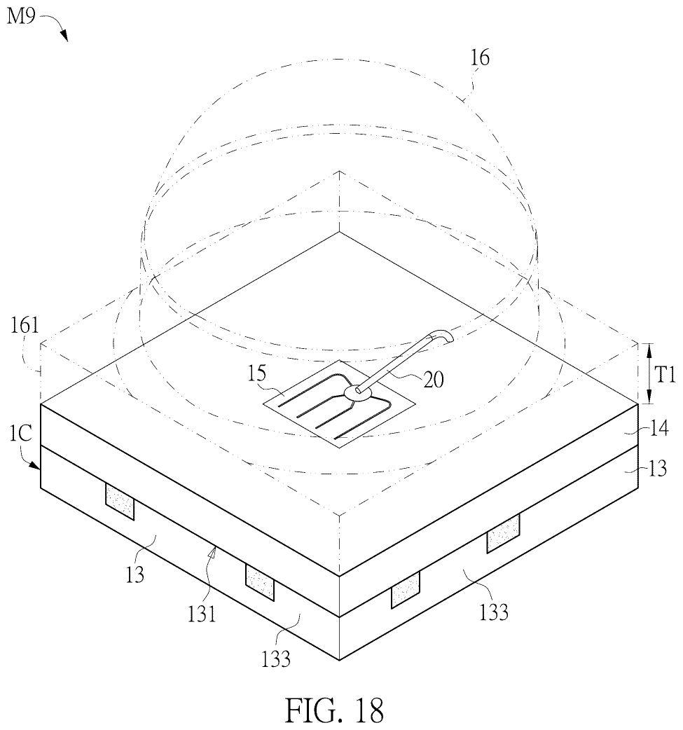

Reference is made to FIGS. 15 to 20, which are respectively schematic views of optoelectronic devices M6 to M11 according to one embodiment of the present disclosure. Each optoelectronic device includes: a package 1C, a photosensitive (or optoelectronic) chip 15, and a covering layer 16. The optoelectronic chip 15 is disposed on the top surface 131 of the package body and is in electrical contact with the second protrusion 122, and electrically connected to the first protrusion 112 via a bonding wire 20. Additionally, in some embodiments, a reflective layer 14 may optionally be disposed on the top surface 131 of the package body 13 surrounding the optoelectronic chip 15, as shown in the embodiment in FIG. 18. According to some embodiments, the reflective layer 14 may be composed of a combination of resin, diffuser and/or reflective particles, such as silicone and titanium dioxide (TiO₂).

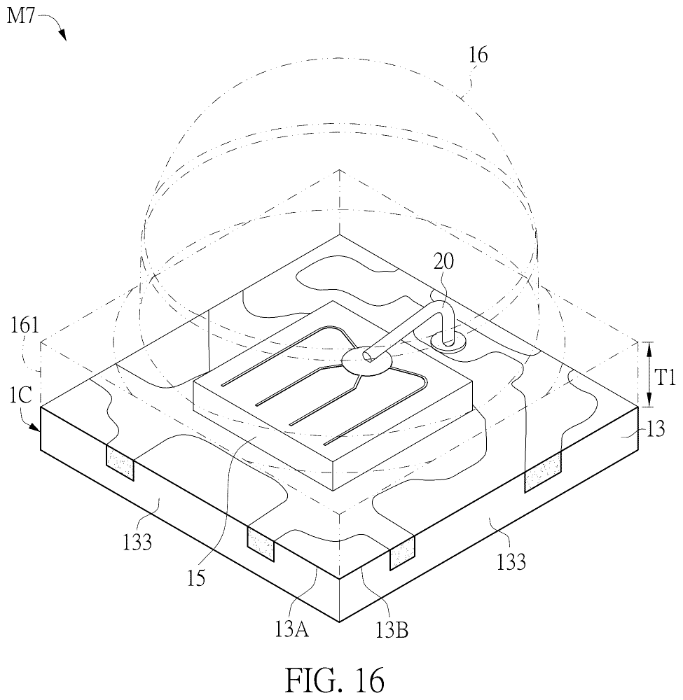

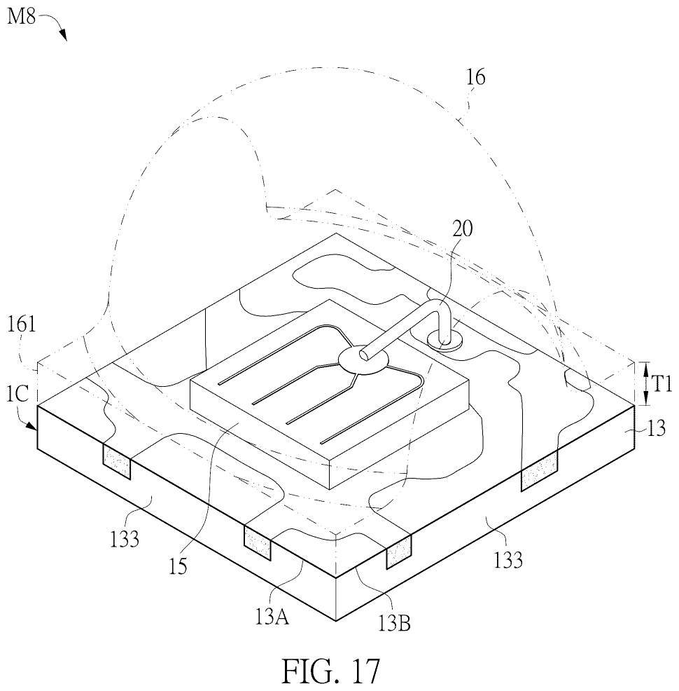

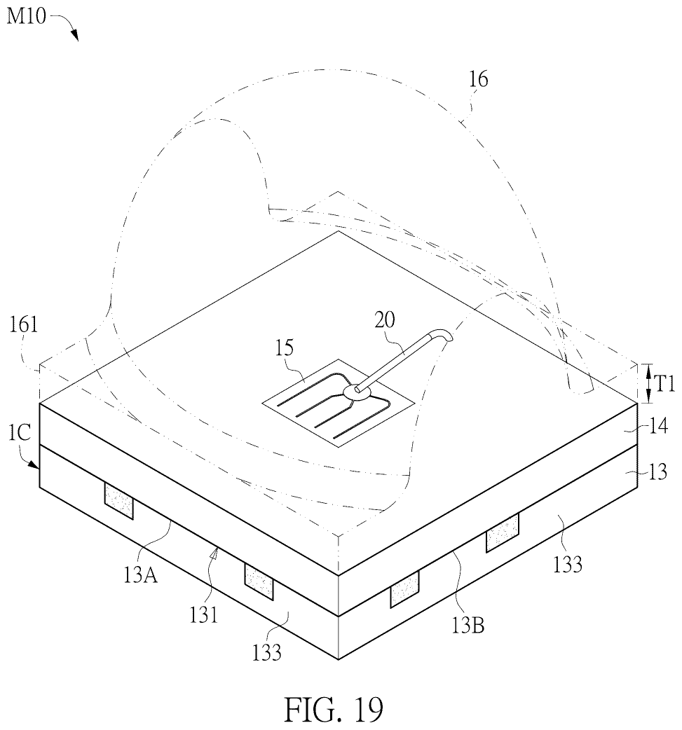

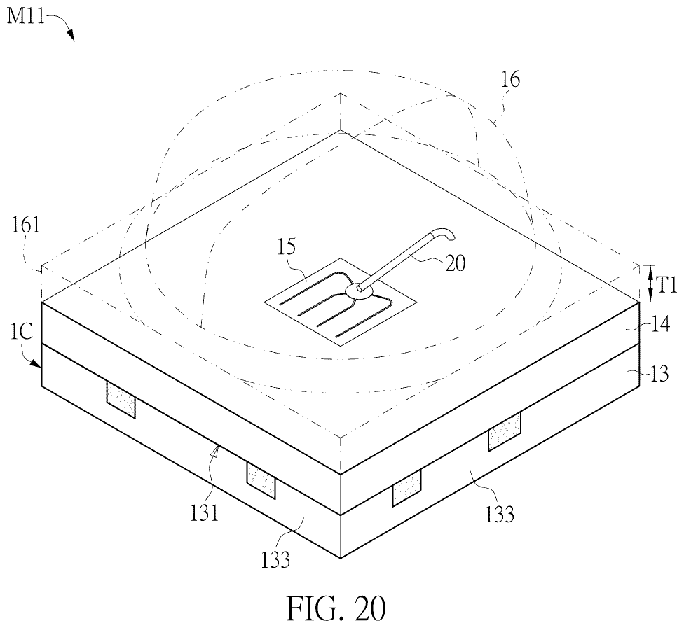

In some embodiments, the covering layer 16 includes an external lens. According to some embodiments, the external lens includes a base 161 with a thickness T1 ranging from 0.05 to 0.50 mm (as can be referred to in FIG. 15 to FIG. 20). In these embodiments, the lens is a curved external lens. When the lens is a symmetrical aspherical lens and the four sides of the lens are not cut, the light output angle of the optoelectronic device can be adjusted to cover 40 degrees to 150 degrees by adjusting the curvature of the lens. For example, in the embodiments shown in FIG. 15 and FIG. 20, the external lens is a symmetric aspheric lens with a nearly flat surface and with four untrimmed edges. The viewing angle of optoelectronic devices M6 and M11 is 130 degrees. In the embodiments shown in FIG. 16 and FIG. 18, the external lens is also a symmetric aspheric lens with four untrimmed edges, and the viewing angle of optoelectronic devices M7 and M9 is 50 degrees. When the lens is an asymmetric lens with trimmed edges on both sides, the viewing angles of the optoelectronic device differ in the two light-emitting directions, The viewing angle of the optoelectronic device ranges from 50 degrees to 120 degrees. For example, in the embodiments shown in FIG. 17 and FIG. 19, the external lens is an asymmetric lens with cut edges on both sides. For optoelectronic devices M8 and M10, the viewing angle corresponding to the side edge 13A of the package body 13 is 70 degrees, and for M8, the viewing angle corresponding to the side edge 13B is 105 degrees. Furthermore, according to the embodiments shown in FIG. 18 to FIG. 20, the optoelectronic devices M6, M7, and M8 are provided with reflective layers 14. Compared to optoelectronic devices M9, M10, and M11 that do not include a reflective layer 14, the brightness of devices with the reflective layer can be enhanced by 10-15%.

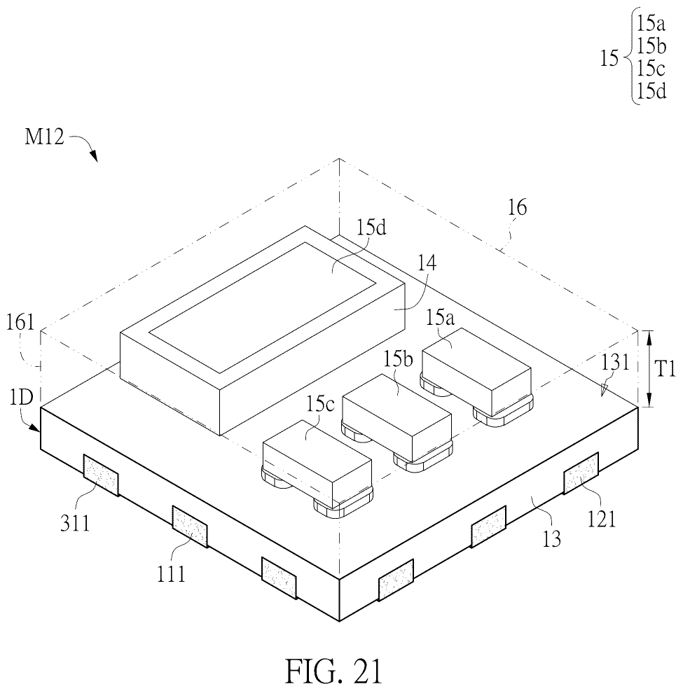

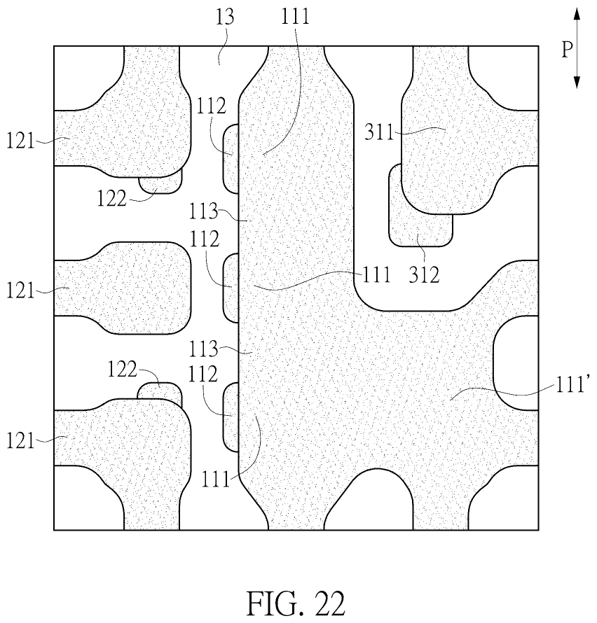

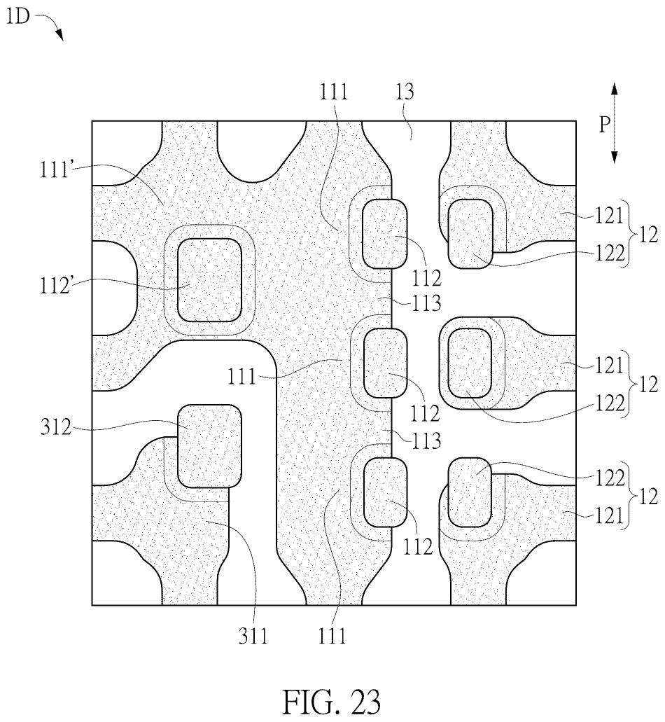

Referring to FIG. 21 to FIG. 23, FIG. 21 is a schematic view of optoelectronic device M12 according to one embodiment of the present disclosure. FIG. 22 is a bottom view of the package 1D in the embodiment shown in FIG. 21. FIG. 23 is a top view of the package 1D in the same embodiment. The optoelectronic device M12 includes a package 1D, an optoelectronic component 15, and a covering layer 16. In this embodiment, the optoelectronic component 15 includes RGB light-emitting diodes 15a, 15b, and 15c, as well as a white light-emitting component 15d. The white light-emitting component 15d includes an optoelectronic chip and a phosphor layer. For example, the combination of a blue-light optoelectronic chip and a yellow-green phosphor (YAG) layer, where the phosphor layer can also be replaced with a phosphor sheet. A reflective layer 14 is disposed on the top surface 131 of the package body 13 and surrounds the white light-emitting component 15d. Furthermore, the top surface of the reflective layer 14 is flush with the top surface of the white light-emitting component 15d. Alternatively, the white light-emitting component 15d can be a CSP (Chip Scale Package) chip, which includes a white-light-emitting component (blue-light optoelectronic chip with a light-conversion component) surrounded by a reflective layer 14.

The package 1D includes a first frame 11, a second frame 12, a third frame 31, and a package body 13. The first frame 11 includes a plurality of first bases 111, a plurality of connection portions 113, and a plurality of first protrusions 112. Adjacent first bases 111 are connected via connection portions 113, with three first bases 111 connected in series along an alignment direction P. The first frame 11 also includes an extended base 111′ extending in a direction perpendicular to an arrangement direction P. A plurality of first protrusions 112 are respectively disposed on the plurality of first bases 111, and the first frame 11 also includes an extended protrusion 112′ disposed on the extended base 111′. The plurality of first protrusions 112 are arranged in the arrangement direction P. The second frame 12 includes a plurality of independent second bases 121 and a plurality of second protrusions 122, with each second protrusion 122 disposed on a corresponding second base 121. The second protrusions 122 are disposed opposite to the first protrusions 112.

The third frame 31 is adjacent to and not connected to the first frame 11. The third frame 31 includes a third base 311 and a third protrusion 312. The third protrusion 312 is disposed on the third base 311 and is arranged opposite to the extended protrusion 112′.

The package body 13 encapsulates the first, second, and third frame. The plurality of first protrusions 112, the extended protrusion 112′, the second protrusions 122, and the third protrusion 312 protrude from the top surface 131 of the package body 13, with a height difference greater than 0 and less than 15 μm, preferably 6-12 μm. Likewise, the bottom surfaces of the first base 111, the extended base 111′, the second bases 121, and the third base 311 are exposed from the bottom surface 132 of the package body 13, with a height difference greater than 0 and less than 15 μm, preferably 6-12 μm.

The optoelectronic component 15 is disposed on the top surface 131 of the package 1D. In the embodiment, each of the RGB light-emitting diodes 15a, 15b, and 15c is electrically connected to a first protrusion 112 and a corresponding second protrusion 122. The white light-emitting component 15d is electrically connected to the extended protrusion 112′ and the third protrusion 312. The covering layer 16 encapsulates the package ID and the three optoelectronic chips (e.g., RGB LEDs 15a, 15b, and 15c) and the white light-emitting component 15d disposed thereon. In the embodiment, the covering layer 16 is an external lens with flat surface, but it is not limited thereto. Depending on requirements, an external lens with curvature, such as a symmetric aspheric lens or an asymmetric lens, can be used, regardless of whether it has a base 161.

However, the aforementioned details are disclosed for exemplary purposes only, and are not meant to limit the scope of the present disclosure.

### BENEFICIAL EFFECTS OF THE EMBODIMENTS

One of the beneficial effects of the present disclosure is that the package provided by the present disclosure can have a better combination effect between the first frame, the second frame and the package body through technical features such as “a first frame including a first body and at least one first protrusion, the at least one first protrusion being located on the first body”, “a second frame arranged opposite to the first frame, the second frame including a second body and at least one second protrusion” and “a distance between the first protrusion and the second protrusion being smaller than a distance between the first body and the second body”, so as to realize a packaging process without setting a frame, and the optoelectronic chip can increase the area of the optoelectronic chip, and simplify the process to improve yield.

One of the beneficial effects of the present disclosure is that an embodiment of the package provided by the present disclosure can improve its bonding ability with optoelectronic chips, optoelectronic components or external substrates through technical features such as “the first protrusion and the second protrusion being exposed on the top surface of the package body” and “the first body and the second body being exposed on the bottom surface of the package body.” In one embodiment, the portion of the first protrusion and the second protrusion protruding from the top surface of the package body is greater than 0 and less than 15 μm. This can prevent the packaging encapsulant from overflowing onto the metal surface, thereby causing poor soldering of the electrical end at the bottom of the chip (with a height difference of about 3 μm), and can reduce the risk of short-circuiting.

One of the beneficial effects of the present disclosure is that an embodiment of the package provided by the present disclosure can also achieve the effect of reducing the thickness of the package body.

One of the beneficial effects of the present disclosure is that in an embodiment of the package provided by the present disclosure, the first body and the second body are simultaneously covered by the package body, which can reduce the invasion of moisture, and strengthen the structure of the first frame and the second frame.

One of the beneficial effects of the present disclosure is that the package provided by the present disclosure can maximize the use of the optoelectronic chip and improve the luminous efficiency through technical features such as “the first lateral protrusion, the first central protrusion and the first connecting protrusion being arranged on the first body at intervals, so as to form a first groove between the first lateral protrusion and the first central protrusion, and a second groove between the first central protrusion and the first connecting protrusion” and “the second protrusion being located on the second body, and the second protrusion corresponding to the periphery of the second body to form a plurality of grooves”.

One of the beneficial effects of the present disclosure is that the optoelectronic device provided by the present disclosure, by virtue of its package, in addition to the aforementioned technical effects, can also improve the luminous efficiency of the optoelectronic chip (and light-emitting component), reduce manufacturing costs, and improve product quality.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A package, comprising:
a first frame including at least one first body and at least one first protrusion, the first protrusion being disposed on the first body;
a second frame arranged opposite to the first frame, the second frame including at least one second body and at least one second protrusion, the second protrusion being disposed on the second body;
a package body encapsulating the first frame and the second frame, and the first protrusion and the second protrusion protruding from a top surface of the package body;
wherein, in a horizontal direction, a distance between the first protrusion and the second protrusion is smaller than a distance between the first body and the second body.

2. The package according to claim 1, wherein, on a same side, a distance between a first side end surface of the first protrusion facing the second protrusion and a first side-portion end surface of the first body is less than 100 μm; on a same side, a distance between a second side end surface of the second protrusion facing the first protrusion and a second side-portion end surface of the first body is less than 100 μm.

3. The package according to claim 1, wherein the height difference between the first protrusion and the second protrusion from the top surface of the package body is greater than 0 and less than 15 μm.

4. The package according to claim 1, wherein a ratio of an exposed area of the first protrusion and the second protrusion to an area of the top surface of the package body is 0.25-0.5.

5. The package according to claim 1, wherein the package has two opposite side edges, the first frame and the second frame has two supporting ends respectively disposed at a center of the side edge, and wherein electrical properties of the two supporting ends are different to each other.

6. The package according to claim 1, wherein each of the first frame and the second frame includes an obliquely extending connection portion, and the two connection portions extend across at least half of the package body.

7. The package according to claim 1, wherein a cross section of the first frame on a central vertical plane is a first Z-shape, and a cross section of the second bracket on the central vertical plane is a second Z-shape.

8. The package according to claim 1, wherein the plurality of first bodies are arranged along an arrangement direction, and two adjacent first bodies are connected by at least one connection portion, and the plurality of first protrusions are respectively disposed on the plurality of first bodies;
the plurality of second bodies are arranged along the arrangement direction, and two adjacent second bodies are connected by at least one connection portion, and the plurality of second protrusions are respectively disposed on the plurality of second bodies, and wherein the first frame and the second frame are arranged opposite to each other, so that the plurality of first protrusions and the plurality of second protrusions respectively correspond to each other and face each other in a mirror-symmetrical manner; and
the plurality of first protrusions and the plurality of second protrusions protruding from a top surface of the package body.

9. The package according to claim 8, wherein the first frame further includes an extension body and an extension protrusion, the extension body is extended in a direction perpendicular to the arrangement direction, the extension protrusion is disposed on the extension body, and the extension protrusion is exposed on the top surface of the package body; and
wherein the package further comprises a third frame adjacent to but not connected to the first frame, the third frame includes a third body and a third protrusion, the third protrusion is disposed on the third body and is arranged opposite to the extension protrusion, and the extension protrusion protrudes from the top surface of the package body.

10. A package, comprising:
a first frame including a first body and a first central protrusion, the first central protrusion is disposed on the first body;
a second frame being arranged opposite to the first frame, the second frame including a second body and a second protrusion, the second protrusion being disposed on the second body, the second protrusion protruding toward the first central protrusion in a horizontal direction, and protruding from a side end surface of the second body; and
a package body encapsulating the first frame and the second frame, the first protrusion and the second protrusion protruding from a top surface of the package body.

11. The package according to claim 10, wherein the first frame further includes a first lateral protrusion and a first connecting protrusion, and wherein the first lateral protrusion, the first central protrusion and the first connecting protrusion are arranged on the first body at intervals, so that a first groove is formed between the first lateral protrusion and the first central protrusion, and a second groove is formed between the first central protrusion and the first connecting protrusion.

12. The package according to claim 10, wherein the second protrusion corresponds to a periphery of the second body and is formed with a plurality of grooves, the plurality of grooves include a first side groove, a central groove and a second side groove, and wherein the first side groove and the second side groove are symmetrical to each other with a central line of the central groove as a symmetry line.

13. The package according to claim 10, wherein a distance between the first body and the second body is 0.12 to 0.5 mm; and a distance between the first central protrusion and the second protrusion is 0.12 to 0.5 mm.

14. The package according to claim 10, wherein a height difference between the first lateral protrusion, the first central protrusion, the first connecting protrusion, and the second protrusion protruding from the top surface of the package body is greater than 0 and less than 15 μm.

15. The package according to claim 10, wherein the first frame includes a first cantilevered connection portion, and the second frame includes a second cantilevered connection portion, and wherein, in the horizontal direction, an adjacent first frame and second frame are obliquely connected via adjacent ones of the first cantilevered connection portion and the second cantilevered connection portion, and on a planar surface, a region where the first frame is located is defined as a first region, a region where the second frame is located is defined as a second region, and the first cantilevered connection portion extends into the second region.

16. An optoelectronic device, comprising:
the package as claimed in claim 1;
an optoelectronic chip arranged on the top surface of the package body, the optoelectronic chip electrically connecting to the first protrusion and the second protrusion respectively; and
a covering layer arranged on the optoelectronic chip.

17. The optoelectronic device according to claim 16, wherein an area corresponding to the first protrusion and the second protrusion is defined as a die-bonding area, and a ratio of a surface area of the optoelectronic chip to the die-bonding area is 1 to 1.5.

18. The optoelectronic device according to claim 16, wherein the covering layer includes a convex lens;
wherein, when the convex lens is an asymmetric lens with cut edges on both sides, a viewing angle of the optoelectronic chip in two light-emitting directions are different; and
wherein, when the convex lens is a symmetrical lens with cut edges on four sides, a viewing angle of the optoelectronic chip in two light-emitting directions is 90 degrees to 125 degrees.

19. The optoelectronic device according to claim 16 further comprising:
a reflective layer disposed on the top surface of the package body and surrounding the optoelectronic chip.

20. An optoelectronic device, comprising:
the package as claimed in claim 9;
a plurality of optoelectronic chips and a white light-emitting component, wherein each of the optoelectronic chips is electrically connected to the first protrusion and the corresponding second protrusion, and the white light-emitting component is electrically connected to the extension protrusion and the third protrusion, respectively; and
a covering layer being disposed on the plurality of optoelectronic chips and the white light-emitting component.
